(19) United States
(12) Patent Application Publication
(10) Pub. No.: US 2014/0177355 A1
(43) Pub. Date: Jun. 26, 2014

(54) NONVOLATILE MEMORY APPARATUS

(71) Applicant: SK HYNIX INC., Icheon-si (KR)

(72) Inventor: Dong Keun KIM, Icheon-si (KR)

(73) Assignee: SK HYNIX INC., Icheon-si (KR)

(21) Appl. No.: 13/846,651

(22) Filed: Mar. 18, 2013

(30) Foreign Application Priority Data
Dec. 21, 2012 (KR) 10-2012-0150162

(51) Int. Cl. G11C 7/06

(52) U.S. Cl. CPC G11C 7/06
USPC 365/189.15

(57) ABSTRACT

A nonvolatile memory apparatus includes a read driver. The read driver unit is configured to apply read current to a memory cell in a normal read operation for outputting data stored in the memory cell, and apply refresh current larger than the read current to the memory cell in a refresh operation.

### CROSS-REFERENCES TO RELATED APPLICATION

The present application claims priority under 35 U.S.C. §119(a) to Korean application number 10-2012-0150162, filed on Dec. 21, 2012, in the Korean Intellectual Property Office, which is incorporated herein by reference in its entirety.

### BACKGROUND

1. Technical Field

Various embodiments generally relate to a semiconductor apparatus, and more particularly, to a memory apparatus including a nonvolatile memory cell.

2. Related Art

A DRAM as a general semiconductor memory apparatus includes a memory cell array constituted by switching elements and capacitors and stores data by charging or discharging the capacitors. The DRAM is widely used since it operates at a very high speed. However, due to the characteristic of memory cells constituted by the capacitors, the DRAM has the characteristic of a volatile memory. Next generation memory apparatuses capable of maximally securing operation speeds and having the characteristic of a nonvolatile memory have been continually developed. A representative example thereof is a resistive memory apparatus which includes a memory cell array constituted by a resistive element with a resistance value variable according to a temperature, current or a voltage. Since the resistive memory apparatus can operate at a high speed while having the characteristic of a nonvolatile memory, it is gaining popularity as an alternative memory which overcomes the disadvantage of the DRAM.

Referring to FIG. 1, the resistive memory cell includes a resistance variable device. The resistance variable device has a resistance value that changes according to current flowing through it. In particular, in the case where the resistance variable device is a phase change element, a state of the phase change elements can be converted from a crystalline state to an amorphous state or from the amorphous state to the crystalline according to the current to store specific data. In general, a set current SET is needed to convert the memory cell into the crystalline state, and a reset current RESET is is needed to convert the memory cell into the amorphous state.

The set current SET and the reset current RESET should be generated as shown in the graph of FIG. 1. The reset current RESET is strongly applied to the memory cell for a short time, and the set current SET is applied for a long time at a magnitude smaller than the reset current RESET. Specifically, the set current SET should have a slow quenching slope that decreases slowly to convert the memory cell MC into the crystalline state and the reset current RESET should have a quickly quenching slope that decreases quickly to convert the memory cell MC into the amorphous state.

A drift phenomenon may be occurred in the resistive memory apparatus using the resistance variable device as a memory member. The drift phenomenon indicates a phenomenon that the resistance value stored in the resistance variable device increases with the lapse of time after data is written in the memory cell. According to FIG. 2A, it can be seen that, when a drift phenomenon occurs, the resistance value of a memory cell in which set data SET is stored and the resistance value of a memory cell in which reset data RESET is stored increase. In particular, in the case where the resistance value of the memory cell in which the set data SET is stored increases, a case is likely to occur, in which the distribution of the set data SET approaches a reference value Rref as shown in FIG. 2B, and accordingly, it may be difficult to verify the set data SET and the reset data RESET in a read operation. In FIG. 2B, a dotted lines indicates distributions when the data are written, and solid lines are distributions with the lapse of time after data is written in the memory cell.

In order to overcome the above-described drift phenomenon, the resistive memory apparatus performs a refresh operation similarly to a DRAM as a volatile memory apparatus. Nevertheless, in order to perform the refresh operation in the resistive memory apparatus, a pre-read operation, a normal read operation and a rewrite operation should be repeated. As a consequence, a lot of time is required, and current consumption markedly increases.

### SUMMARY

In an embodiment of the present invention, a nonvolatile memory apparatus includes: a read driver unit configured to apply read current to a memory cell in a normal read operation for outputting a data stored in the memory cell, and apply a refresh current being greater than the read current to the memory cell in a refresh operation.

In an embodiment of the present invention, a nonvolatile memory apparatus includes: a voltage generation unit configured to provide a power supply voltage to a sensing node; and a read current generation unit electrically coupled with the sensing node, and configured to provide read current and a refresh current being greater than the read current to a memory cell in response to a read signal and a refresh signal.

In an embodiment of the present invention, a nonvolatile is memory apparatus includes: a voltage generation unit configured to provide a power supply voltage to a sensing node; a sense amplifier coupled with the sensing node, and configured to sense a sensing voltage and generate a data output signal; a data sensing unit configured to generate a set refresh signal in response to the data output signal; and a read current generation unit configured to provide read current and a refresh current being greater than the read current to a memory cell in response to a read signal and the set refresh signal.

In an embodiment of the present invention, a nonvolatile memory apparatus includes: a voltage generation unit configured to provide a variable voltage to a sensing node in response to a refresh signal and a read signal; and a read current generation unit electrically coupled with the sensing node, and configured to provide read current and refresh current being greater than the read current to a memory cell in response to the read signal and the refresh signal.

In an embodiment of the present invention, a semiconductor system comprises a semiconductor memory apparatus configured to include a memory cell, to provide a refresh current being greater than a read current and smaller than a current which includes max value to not change a resistivity of data stored in the memory cell in response to a refresh signal, and a memory controller to control operation modes of the semiconductor memory apparatus.

### BRIEF DESCRIPTION OF THE DRAWINGS

Features, aspects, and embodiments are described in conjunction with the attached drawings, in which:

FIG. 1 is a graph showing the waveform of write current necessary to store data in a resistive memory cell;

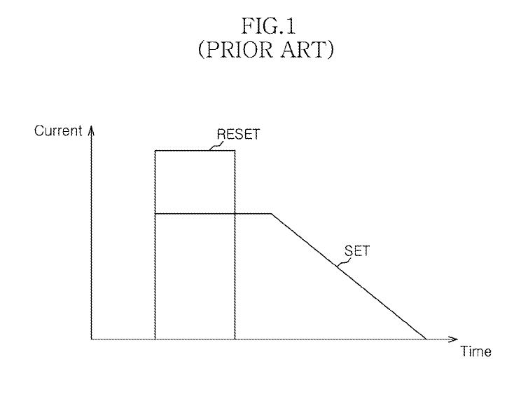

FIGS. 2A and 2B are graphs showing a drift phenomenon which occurs in a resistive memory cell;

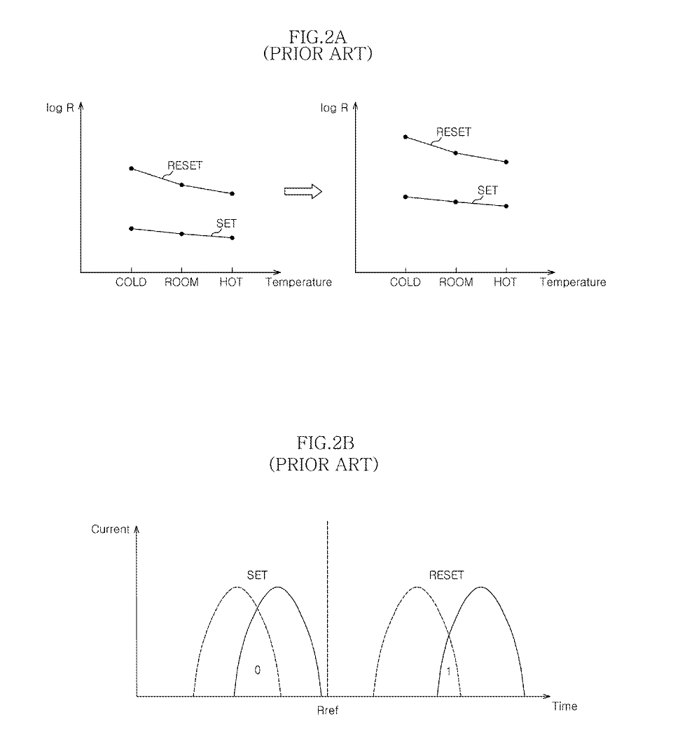

FIG. 3 is a diagram schematically showing the configuration of a nonvolatile memory apparatus in accordance with an embodiment of the present invention;

FIG. 4 is a graph showing the waveforms of current used in the nonvolatile memory apparatus in accordance with an embodiment of the present invention;

FIG. 5 is a diagram schematically showing the configuration of a nonvolatile memory apparatus in accordance with an embodiment of the present invention;

FIG. 6 is a diagram schematically showing the configuration of a nonvolatile memory apparatus in accordance with an embodiment of the present invention;

FIG. 7 is a diagram showing the configuration of an exemplary embodiment of the voltage generation unit of FIG. 6.

FIG. 8 is a schematic block diagram of a memory system according to an embodiment of the present invention; and

FIG. 9 is a schematic block diagram of a computing system including a flash memory device according to an embodiment of the present invention.

### DETAILED DESCRIPTION

Hereinafter, a nonvolatile memory apparatus according to the present invention will be described below with reference to the accompanying drawings through exemplary embodiments.

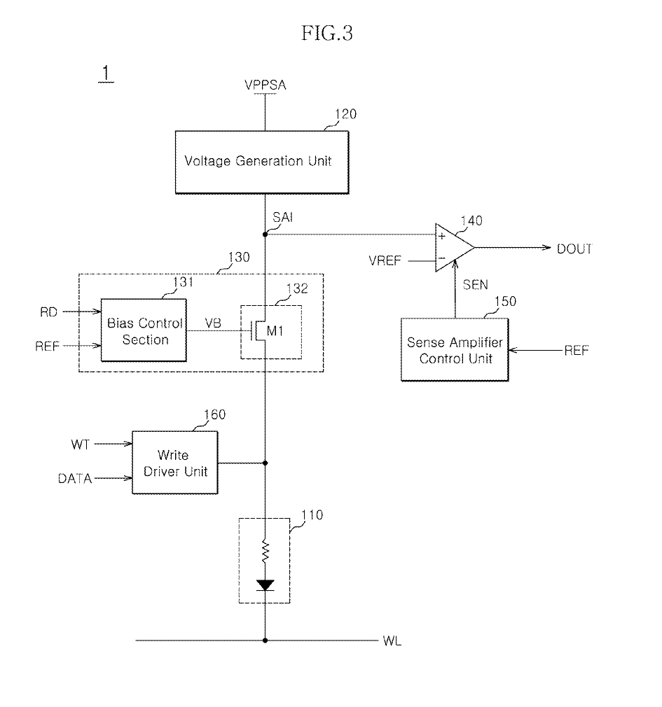

Referring to FIG. 3, the nonvolatile memory apparatus 1 may include a memory cell 110 and a read driver block RDB. Although the FIG. 3 shows one memory cell, the memory cell 110 may include a plurality of the memory cell. The memory cell 110 may include a switching device and a resistance variable device connected to the switching device to store data according to a change in resistance value. The switching device may be a diode to cause current to flow in one direction. The resistance variable device may be a substantial memory layer, for example, the resistance variable device may included a PCMO layer which is a material for a ReRAM, a chalcogenide layer which is a material for a PCRAM, a magnetic layer which is a material for a MRAM, a magnetization reversal device layer which is a material for a spin-transfer torque magnetoresistive RAM (STTMRAM), or a polymer layer which is a material for a polymer RAM (PoRAM).

The read driver block RDB may be configured to perform a normal read operation and a refresh operation. The normal read operation may indicate an operation for reading out and outputting the data stored in the memory cell 110, and the refresh operation may indicate an operation for retaining the data stored in the is memory cell 110. The read driver block may apply a read current to the memory cell 110 in the normal read operation, and may apply a refresh current being greater than the read current to the memory cell 110 in the refresh operation. The read driver block RDB may maintain the data stored in the memory cell 110 by applying the refresh current being greater than the read current to the memory cell 110 and smaller than the set current or the reset current. For example, an upper limit of the refresh current may have a max value to not change a resistivity of data stored in the memory cell. The read driver block RDB may include a voltage generation unit 120 and a read current generation unit 130. The voltage generation unit 120 may be configured to apply a power supply voltage VPPSA to a sensing node SAI. The power supply voltage VPPSA may be a voltage which has a level higher than that of an external voltage, and may be generated from a booster circuit (not shown) which is provided in the nonvolatile memory apparatus 1.

The read current generation unit 130 may be configured to provide the read current and the refresh current to the memory cell 110 in response to a read signal RD and a refresh signal REF. The read signal RD may be enabled when the read operation is performed, and the refresh signal REF may be enabled when the refresh operation is performed. The read current generation unit 130 may provide the read current to the memory cell 110 in response to the read signal RD, and provide the refresh current to the memory cell 110 in response to the refresh signal REF. The refresh current may is be larger than the read current. The memory cell 110, more detail, the resistance variable device has a resistance value that varies according to a magnitude (amount) of a current for writing the data. If the current corresponding to data is applied in a write operation of the semiconductor memory apparatus 1, as the resistance value of the memory cell 110 varies, the data may be stored. However, as aforementioned above in the background, a drift phenomenon occurs with the lapse of time. In this regard, in the conventional art, the drift phenomenon is corrected by performing a refresh operation. The refresh operation in the conventional art requires a number of steps. As a consequence, a time required for performing the refresh operation is lengthened, and current consumption increases. In the nonvolatile memory apparatus 1 in accordance with the embodiment of the present invention, the drift phenomenon may be corrected by applying refresh current to the memory cell 110. Accordingly, the refresh operation may be performed within a short time, and current consumption may be significantly reduced.

The read current generation unit 130 may include a bias control section 131 and a driver 132. The bias control section 131 is configured to generate a bias voltage VB in response to the read signal RD and the refresh signal REF. More detailed, the bias control section 131 may generate the bias voltage VB of a first level in response to the read signal RD, and may generate the bias voltage VB of a second level in response to the refresh signal REF. The second level may be higher than the first level.

The driver 132 is configured to adjust the current provided to the memory cell 110, in response to the bias voltage VB. The driver 132 may include a transistor M1. The transistor M1 may include a gate provided the bias voltage, a drain (or source) coupled with the sensing node SAI and a source (or drain) coupled with the memory cell 110. For example, the source (of the drain) may be electrically coupled to the resistance variable device of the memory cell 110, and the switching device may be electrically coupled to a word line WL. The power supply voltage VPPSA is applied to the sensing node SAI by the voltage generation unit 120. The turn-on degree of the transistor M1, that is, a threshold voltage of the transistor M1 may be changed according to a level of the bias voltage VB. Thus, a current path provided from the power supply voltage VPPSA is generated in the driver 132 and a size of the current path may be adjusted by the level of the bias voltage VB. That is to say, the transistor M1 generates larger current (or current path) when receiving the bias voltage VB of the second level than when receiving the bias voltage VB of the first level.

In FIG. 3, the nonvolatile memory apparatus 1 may further include a sense amplifier 140 and a sense amplifier control unit 150. The sense amplifier 140 is configured to sense the voltage level of the sensing node SAI and generate a data output signal DOUT. The sense amplifier 140 is configured to compare the voltage level of the sensing node SAI and the level of a reference voltage VREF in a read operation, and generate the data output signal DOUT as the is comparing result. The read operation may include all kinds of read operations such as a normal read operation, a verifying read operation and a pre-read operation.

The sense amplifier control unit 150 is configured to disable the sense amplifier 140 in response to the refresh signal REF. The sense amplifier control unit 150 is configured to generate a sense amplifier control signal SEN when the refresh signal REF is enabled in the refresh operation. The sense amplifier control signal SEN is inputted to the sense amplifier 140 to deactivate the sense amplifier 140.

The nonvolatile memory apparatus 1 may further include a write driver unit 160. The write driver unit 160 is configured to provide write current to the memory cell 110 in response to a write signal WT and data DATA. The write driver unit 160 may be configured to generate set current SET for storing set data and reset current RESET for storing reset data, in response to the write signal WT and the data DATA.

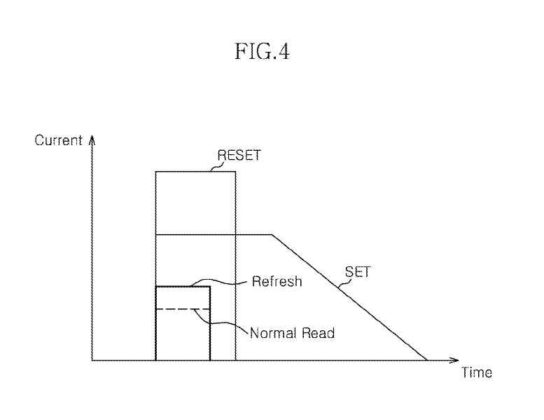

Referring to FIG. 4, the refresh current used in the refresh operation may be larger than the read current used in the normal read operation. Further, the refresh current may be smaller than the set current SET and the reset current RESET.

The refresh operation of the nonvolatile memory apparatus 1 according to the embodiment of the present invention will be described below with reference to FIGS. 3 and 4. If the refresh signal REF is enabled to perform the refresh operation, the read current is generation unit 130 provides the refresh current being larger than a normal read current to the memory cell 110. The sense amplifier control unit 150 provides the sense amplifier control signal SEN to the sense amplifier 140, thereby disabling the sense amplifier 140. The memory cell 110 receives the refresh current being larger than the normal read current. Since the sufficient refresh current is provided to the memory cell 110, a gradually amorphizing of the resistance variable device due to the drift phenomenon is suppressed by the refresh current. Thus, as the refresh current is applied, a resistance variation of the memory cell 110 by the drift phenomenon may be corrected.

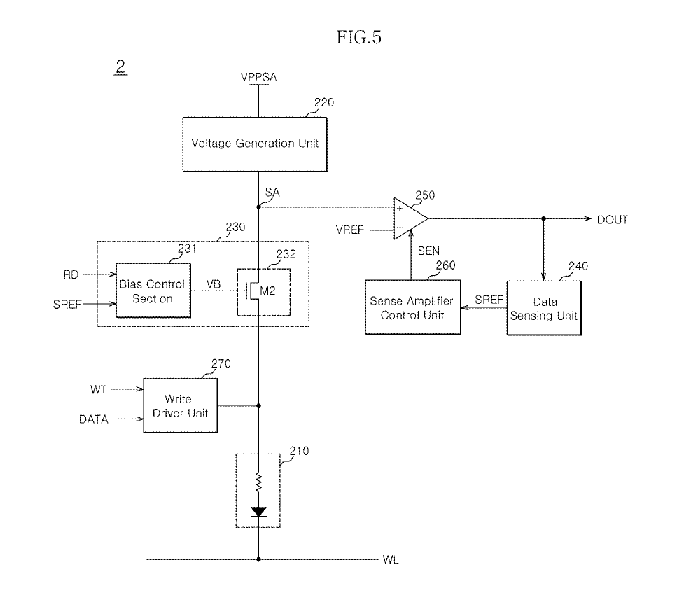

Referring to FIG. 5, the nonvolatile memory apparatus 2 performs a refresh operation only for a memory cell in which the set data is stored and may thereby efficiently reduce current consumed in the refresh operation. In general, a memory cell in which the reset data is stored is a high resistant state, and the memory cell in which the set data is stored is a low resistant state. Since the drift phenomenon is that a resistance value of the resistance variable device is increased, a set resistant state shifts toward a reference value being positioned between the set resistant state and the reset resistant state and a reset resistant state shift far from the reference value. Hence, it is essential to correct the set resistant state. Conversely, it is not necessary to correct the reset resistant state.

The nonvolatile memory apparatus 2 may include a memory cell 210, a voltage generation unit 220, a read current generation unit 230, and a data sensing unit 240. The memory cell 210 and the voltage generation unit 220 may be the same as the memory cell 110 and the voltage generation unit 120 of FIG. 3. The read current generation unit 230 is configured to generate a read current and a refresh current in response to a read signal RD and a set refresh signal SREF. The refresh current may be larger than the read current. The read current generation unit 230 provides the read current to the memory cell 210 in response to the read signal RD, and provides the refresh current to the memory cell 210 in response to the set refresh signal SREF.

The data sensing unit 240 is configured to generate the set refresh signal SREF in response to a data output signal DOUT. When the data output signal DOUT is outputted at, for example, a low level, the data sensing unit 240 senses that the data stored by the memory cell 210 is set data, and generates the set refresh signal SREF. When the data output signal DOUT is outputted at, for example, a high level, since the data stored by the memory cell 210 is reset data, the data sensing unit 240 does not enable the set refresh signal SREF.

Since the read current generation unit 230 provides the refresh current to the memory cell 210 when the set refresh signal SREF is enabled, it does not provide the refresh current to the memory cell 210 which stores reset data and provides the refresh current to only the memory cell 210 which stores set data. The read current generation unit 230 may include a bias control section 231 and a driver 232. The driver 232 may include a transistor M2. The is configuration of the read current generation unit 230 is the same as the read current generation unit 130 of FIG. 3 except that the refresh signal REF is replaced with the set refresh signal SREF.

In FIG. 5, the nonvolatile memory apparatus 2 may further include a sense amplifier 250, a sense amplifier control unit 260, and a write driver unit 270. The sense amplifier 250 may be electrically coupled with a sensing node SAI, and is configured to compare the voltage level of the sensing node SAI and the level of a reference voltage VREF and output the data output signal DOUT. The sense amplifier control unit 260 is configured to disable the sense amplifier 250 in response to the set refresh signal SREF. The write driver unit 270 is configured to provide write current to the memory cell 210 to write data in a write operation.

The nonvolatile memory apparatus 2 performs the refresh operation as follows. First, a pre-read operation is performed for the memory cell 210. When performing the pre-read operation, the read current generation unit 230 provides the read current to the memory cell 210 in response to the read signal RD. If the read current is provided, the voltage level of the sensing node SAI varies according to the resistance value of the memory cell 210. In the case where the memory cell 210 is the high resistant state, the voltage level of the sensing node SAI is to be high, and, in the case where the memory cell 210 is the low resistant state, the voltage level of the sensing node SAI is to be lower than the high resistant state. The sense amplifier 250 compares the voltage level of the sensing node SAI and the level of the reference voltage VREF and generates the data output signal DOUT.

The data sensing unit 240 generates the set refresh signal SREF when the data output signal DOUT is a low level, that is, the data stored in the memory cell 210 is set data. If the set refresh signal SREF is generated, the sense amplifier control unit 260 generates a sense amplifier control signal SEN and thereby disables the sense amplifier 250. The read current generation unit 230 provides the refresh current to the memory cell 210 in response to the set refresh signal SREF, and the resistance value of the memory cell 210 may be corrected by the refresh current. For example, the set refresh current may be greater than the read current and smaller than the set current.

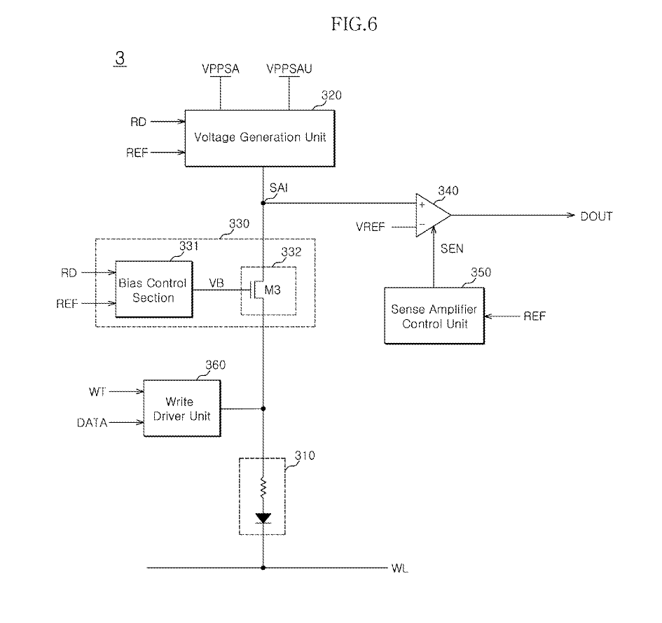

Referring to FIG. 6, a nonvolatile memory apparatus 3 requires a refresh current larger than read current used in a normal read operation is necessary in order for a refresh operation. During the refresh operation, the nonvolatile memory apparatus 3 may be provided a power supply voltage of a higher level than when a normal read operation is performed, such that the refresh current may be stably generated.

In detail, the nonvolatile memory apparatus 3 may include a memory cell 310, a voltage generation unit 320, and a read current generation unit 330. The memory cell 310 and the read current generation unit 330 may be substantially the same as the memory cell 110 and the read current generation unit 130 of FIG. 3. The read is current generation unit 330 may a bias control section 331 and a driver 332. The driver 332 includes a transistor M3.

The voltage generation unit 320 may be configured to provide variable voltages to a sensing node SAI in response to a read signal RD and a refresh signal REF. The voltage generation unit 320 may provide a first power supply voltage VPPSA to the sensing node SAI in response to the read signal RD, and may provide a second power supply voltage VPPSAU to the sensing node SAI in response to the refresh signal REF. The second power supply voltage VPPSAU may be higher than the first power supply voltage VPPSA. The first power supply voltage VPPSA and the second power supply voltage VPPSAU may be internal voltages which may be generated from a booster circuit (not shown) included in the nonvolatile memory apparatus 3. The voltage generation unit 320 may provide the second power supply voltage VPPSAU to the sensing node SAI in response to the refresh signal REF, such that the refresh current may be stably generated by the read current generation unit 330.

Further, the nonvolatile memory apparatus 3 may include a sense amplifier 340, a sense amplifier control unit 350, and a write driver unit 360. The sense amplifier 340, the sense amplifier control unit 350 and the write driver unit 360 may be the same as the sense amplifier 140, the sense amplifier control unit 150 and the write driver unit 160 as like FIG. 3.

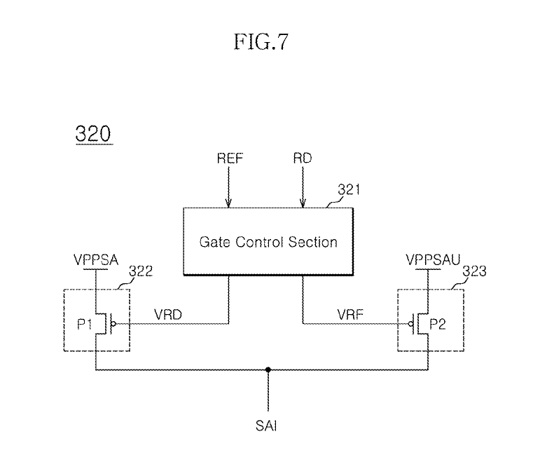

Referring to FIG. 7, the voltage generation unit 320 may include a gate control section 321, and first and second voltage drivers 322 and 323. The gate control section 321 may be configured to receive the read signal RD and the refresh signal REF and generate first and second gate voltages VRD and VRF. The gate control section 321 may generate the first gate voltage VRD in response to the read signal RD, and may generate the second gate voltage VRF in response to the refresh signal REF.

The first voltage driver 322 may be configured to provide the first power supply voltage VPPSA to the sensing node SAI in response to the first gate voltage VRD. The first voltage driver 322 includes a first PMOS transistor P1. The first PMOS transistor P1 has the gate which receives the first gate voltage VRD, the source which receives the first power supply voltage VPPSA, and the drain which is electrically coupled with the sensing node SAI. The first PMOS transistor P1 may drive the sensing node SAI with the first power supply voltage VPPSA when being turned on in response to the first gate voltage VRD, thereby providing the first power supply voltage VPPSA to the sensing node SAI.

The second voltage driver 323 may be configured to provide the second power supply voltage VPPSAU to the sensing node SAI in response to the second gate voltage VRF. The second voltage driver 323 includes a second PMOS transistor P2. The second PMOS transistor P2 has the gate which receives the second gate voltage VRF, the source which receives the second power supply voltage VPPSAU, and the drain which is coupled with the sensing node SAI. The second PMOS transistor P2 may drive the sensing node SAI with the second power supply voltage VPPSAU when being turned on in response to the second gate voltage VRF, thereby providing the second power supply voltage VPPSAU to the sensing node SAI.

The refresh operation of the nonvolatile memory apparatus 3 will be described below with reference to FIGS. 6 and 7. If the refresh signal REF is enabled to perform the refresh operation, the voltage generation unit 320 provides the second power supply voltage VPPSAU with a level higher than the first power supply voltage VPPSA to the sensing node SAI. The sense amplifier control unit 350 generates a sense amplifier control signal SEN and thereby disables the sense amplifier 340. The read current generation unit 330 provides the refresh current to the memory cell 310 by the second power supply voltage VPPSAU in response to the refresh signal REF. The memory cell 310 may be corrected in the resistance value thereof by receiving the refresh current.

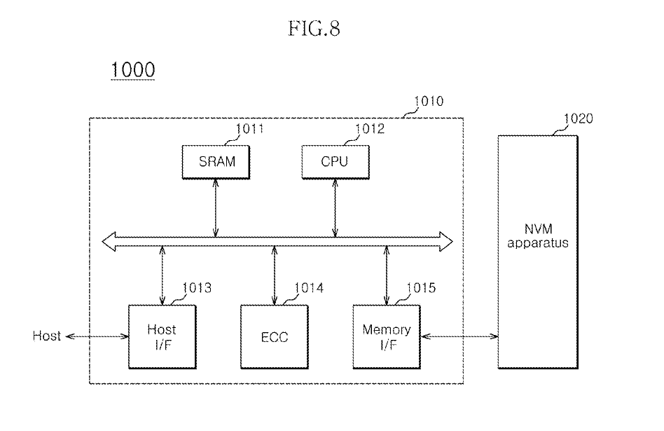

Referring to FIG. 8, a memory system 1000 according to an embodiment of the present invention may include a non-volatile memory apparatus 1010 and a memory controller 1020.

The non-volatile memory apparatus 1020 may be configured to include the above-described semiconductor memory apparatus to provide a refresh current to memory cells during a refresh operation. The memory controller 1010 may be configured to control the non-volatile memory apparatus 1020 in a general operation mode such as a write mode, a read mode or a refresh mode.

The memory system 1000 may be a solid state disk (SSD) is or a memory card in which the memory device 1120 and the memory controller 1110 are combined. SRAM 1011 may function as an operation memory of a processing unit (CPU) 1012. A host interface 1013 may include a data exchange protocol of a host being coupled to the memory system 1000. An error correction code (ECC) block 1014 may detect and correct errors included in a data read from the non-volatile memory apparatus 1020. A memory interface (I/F) 1015 may interface with the non-volatile memory apparatus 1020. The CPU 1012 may perform the general control operation for data exchange of the memory controller 1010.

Though not illustrated in FIG. 8, the memory system 1000 may further include ROM that stores code data to interface with the host. In addition, the non-volatile memory apparatus 1020 may be a multi-chip package composed of a plurality of resistive memory chips, such as a PCRAM or ReRAM. The memory system 1000 may be provided as a storage medium with a low error rate and high reliability. A memory system such as a Solid State Disk (SSD), on which research has been actively carried out, may include a flash memory device according to an embodiment of the present invention. In this case, the memory controller 1010 may be configured to communicate with the outside (e.g., a host) through one of the interface protocols including USB, MMC, PCI-E, SATA, PATA, SCSI, ESDI and IDE.

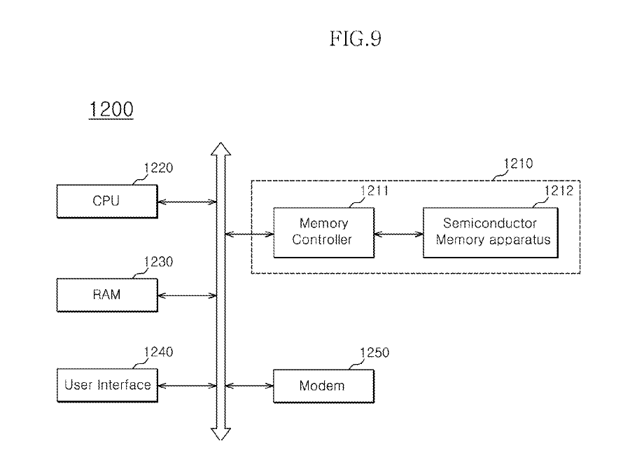

Referring to FIG. 9, a computing system 1200 may include a microprocessor (CPU) 1220, RAM 1230, a user interface 1240, a is modem 1250, such as a baseband chipset, and a memory system 1210 that are electrically coupled to a system bus 1260. In addition, if the computing system 1200 is a mobile device, then a battery (not illustrated) may be additionally provided to apply an operating voltage to the computing system 1200. Though not illustrated in FIG. 9, the computing system 1200 may further include application chipsets, a Camera Image Processor (CIS), or mobile DRAM. The memory system 1210 may include a semiconductor memory apparatus 1212 according to the above embodiments. That is, the memory system 1210 may form a Solid State Drive/Disk (SSD) that uses a non-volatile memory to store data. The memory system 1210 may be provided as a fusion flash memory.

While certain embodiments have been described above, it will be understood to those skilled in the art that the embodiments described are by way of example only. Accordingly, the nonvolatile memory apparatus described herein should not be limited based on the described embodiments. Rather, the nonvolatile memory apparatus described herein should only be limited in light of the claims that follow when taken in conjunction with the above description and accompanying drawings.

What is claimed is:

1. A nonvolatile memory apparatus comprising:
a read driver unit configured to apply a read current to a memory cell in a normal read operation for outputting a data stored in the memory cell, and apply a refresh current being greater than the read current to the memory cell in a refresh operation.

2. The nonvolatile memory apparatus according to claim 1, wherein the refresh current is smaller than a set current and a reset current for writing a data in the memory cell.

3. A nonvolatile memory apparatus comprising:
a voltage generation unit configured to provide a power supply voltage to a sensing node; and
a read current generation unit electrically coupled with the sensing node, and configured to selectively provide a read current and a refresh current being greater than the read current to a memory cell in response to a read signal and a refresh signal.

4. The nonvolatile memory apparatus according to claim 3, wherein the read current generation unit comprises:
a bias control section configured to generate a bias voltage in response to the read signal and the refresh signal; and
a driver configured to control a magnitude of current provided to the memory cell according to the bias voltage.

5. The nonvolatile memory apparatus according to claim 4, wherein the driver comprises a transistor having a gate which receives the bias voltage, one of a source and a drain which is electrically coupled with the sensing node, and the other of the source and the drain which is electrically coupled with the memory cell.

6. The nonvolatile memory apparatus according to claim 3, further comprising:
a sense amplifier configured to compare a voltage level of the sensing node with a level of a reference voltage and generate a data output signal.

7. The nonvolatile memory apparatus according to claim 6, further comprising:
a sense amplifier control unit configured to disable the sense amplifier in response to the refresh signal.

8. The nonvolatile memory apparatus according to claim 3, further comprising:
a write driver unit configured to provide a set current and a reset current to the memory cell in response to a write signal and a data,
wherein the refresh current is smaller than the set current and the reset current.

9. A nonvolatile memory apparatus comprising:
a voltage generation unit configured to provide a power supply voltage to a sensing node;
a sense amplifier electrically coupled with the sensing node, and configured to sense a sensing voltage and generate a data output signal;
a data sensing unit configured to generate a set refresh signal in response to the data output signal; and
a read current generation unit configured to selectively provide a read current and a refresh current being greater than the read current to a memory cell in response to a read signal and the set is refresh signal.

10. The nonvolatile memory apparatus according to claim 9, wherein the data sensing unit enables the set refresh signal when a set data is sensed through the sense amplifier on the basis of the data output signal, and disables the set refresh signal when reset data is sensed through the sense amplifier on the basis of the data output signal.

11. The nonvolatile memory apparatus according to claim 9, further comprising:
a sense amplifier control unit configured to disable the sense amplifier in response to the set refresh signal.

12. The nonvolatile memory apparatus according to claim 9, wherein the read current generation unit comprises:
a bias control section configured to generate a bias voltage in response to the read signal and the set refresh signal; and
a driver configured to control a magnitude of current provided to the memory cell according to the bias voltage.

13. The nonvolatile memory apparatus according to claim 9, further comprising:
a write driver unit configured to provide a set current and a reset current to the memory cell in response to a write signal and a is data,
wherein the refresh current is smaller than the set current

14. A nonvolatile memory apparatus comprising:
a voltage generation unit configured to provide variable voltages to a sensing node in response to a refresh signal and a read signal; and
a read current generation unit electrically coupled with the sensing node, and configured to provide a read current and a refresh current being greater than the read current to a memory cell in response to the read signal and the refresh signal.

15. The nonvolatile memory apparatus according to claim 14, wherein the voltage generation unit is configured to provide a first power supply voltage to the sensing node in response to the read signal, and provide a second power supply voltage with a level higher than the first power supply voltage to the sensing node in response to the refresh signal.

16. The nonvolatile memory apparatus according to claim 14, wherein the read current generation unit comprises:
a bias control section configured to generate a bias voltage in response to the read signal and the refresh signal; and
a driver configured to control a magnitude of current provided to the memory cell according to the bias voltage.

17. The nonvolatile memory apparatus according to claim 14, further comprising:
a sense amplifier configured to compare a voltage level of the sensing node with a level of a reference voltage and generate a data output signal.

18. The nonvolatile memory apparatus according to claim 17, further comprising:
a sense amplifier control unit configured to disable the sense amplifier in response to the refresh signal.

19. The nonvolatile memory apparatus according to claim 14, further comprising:
a write driver unit configured to provide a set current and a reset current to the memory cell in response to a write signal and a data,
wherein the refresh current is smaller than the set current and the reset current.

20. A semiconductor system comprising:
a semiconductor memory apparatus configured to include a memory cell, to provide a refresh current being greater than a read current and smaller than a current which includes a max value to not change a resistivity of data stored in the memory cell in response to is a refresh signal; and
a memory controller to control operation modes of the semiconductor memory apparatus.

21. The semiconductor system according to claim 20, wherein the refresh current is provided to the memory cell, when the memory cell includes a set data.

22. The semiconductor system according to claim 20, wherein the semiconductor memory apparatus is configured to provide a power supply voltage,
the refresh current is determined by a level of the refresh signal and the power supply voltage.

23. The semiconductor system according to claim 20, wherein the semiconductor memory apparatus is configured to provide a first power supply voltage and a second power supply voltage being greater than the first power supply voltage,
the refresh current is determined by the second power supply voltage in response to the refresh signal.
